(19) United States
(12) Patent Application Publication
(10) Pub. No.: US 2025/0192519 A1
(43) Pub. Date: Jun. 12, 2025

(54) OPTOELECTRONIC SEMICONDUCTOR COMPONENT, METHOD FOR PRODUCING THE OPTOELECTRONIC SEMICONDUCTOR COMPONENT AND LIDAR SYSTEM

(71) Applicant: ams-OSRAM International GmbH, Regensburg (DE)

(72) Inventors: Martin Rudolf BEHRINGER, Regensburg (DE); Hubert HALBRITTER, Dietfurt-Toeging (DE)

(73) Assignee: ams-OSRAM International GmbH, Regensburg (DE)

(21) Appl. No.: 18/005,468

(22) PCT Filed: Jul. 8, 2021
(86) PCT No.: PCT/EP2021/069024

§ 371 Date: Dec. 4, 2023

(30) Foreign Application Priority Data
Jul. 16, 2020 (DE) 102020118824.2

(51) Int. Cl. H01S 5/183; G01S 7/481; H01S 5/30; H01S 5/42

(52) U.S. Cl. CPC H01S 5/18338; H01S 5/18311; H01S 5/1833; H01S 5/18352; H01S 5/3095; H01S 5/426; G01S 7/4814

(57) ABSTRACT

The invention related to an optoelectronic device (10) comprising a semiconductor layer stack (109), in which a surface-emitting laser diode is formed. The semiconductor layer stack (109) comprises a first aperture stop (115). A dimension of the first aperture stop (115) in a first horizontal direction is smaller than 50 μm and smaller than the dimension of the first aperture stop (115) in a second horizontal direction.

### BACKGROUND

Light Detection and Ranging (LIDAR) systems are increasingly used in vehicles, such as for autonomous driving. For example, they are used to measure distances or to detect objects. In order to be able to reliably identify objects at a greater distance, laser light sources with correspondingly high power are required. In particular, a high beam quality is desirable in order for the emitted laser beam to occur a small point at a far distance. Due to the beam quality M² and their near/far fields, edge emitters are usually very well suited for such applications. However, with edge-emitting lasers, the emission wavelength strongly depends on the ambient temperature.

For this reason, efforts are being made to provide surface-emitting semiconductor lasers having improved characteristics.

It is an object of the present invention to provide an improved optoelectronic semiconductor device.

### SUMMARY

According to embodiments, the object is achieved by the subject matter of the independent claims. Advantageous enhancements are defined in the dependent claims.

An optoelectronic semiconductor device comprises a semiconductor layer stack in which a surface-emitting laser diode is formed. The semiconductor layer stack comprises a first aperture stop. A dimension of the first aperture stop in a first horizontal direction is smaller than 50 μm and smaller than the dimension of the first aperture stop in a second horizontal direction.

For example, the dimension of the first aperture stop in the second horizontal direction may be greater than 100 μm.

The surface-emitting laser diode may comprise a plurality of laser elements stacked one above the other.

The optoelectronic semiconductor device may further comprise a tunnel junction which is adapted to connect two adjacent ones of the plurality of laser elements stacked one above the other.

According to embodiments, the optoelectronic semiconductor device further comprises a second aperture stop adjacent to the tunnel junction, wherein a dimension of the second aperture stop in the first horizontal direction is smaller than 50 μm. The optoelectronic semiconductor device may furthermore comprise a third aperture stop adjacent to an active zone, wherein a dimension of the third aperture stop in the second horizontal direction is greater than 100 μm.

The surface-emitting laser diode may be formed in a semiconductor layer stack which is patterned into a mesa.

The optoelectronic semiconductor device may further comprise an absorbent material on a sidewall of the mesa. For example, the absorbent material may comprise a semiconductor material having a band gap smaller than that corresponding to a wavelength emitted by the laser diode. A refractive index of the absorbent material may be at least as large as the refractive index of a semiconductor material of an active zone of the laser diode.

For example, a sidewall of the mesa is curved along the second horizontal direction. According to further embodiments, a sidewall of the mesa may intersect a vertical direction.

According to embodiments, a sidewall of the first aperture stop may extend along a direction intersecting the first and second horizontal directions. According to further embodiments, a sidewall of the first aperture stop may be patterned along the second direction. Furthermore, a sidewall of the first aperture stop may be curved along the first or second direction.

A method of manufacturing an optoelectronic semiconductor device comprises forming a semiconductor layer stack for forming a surface-emitting laser diode, and forming a first aperture stop. A dimension of the first aperture stop in a first horizontal direction is smaller than 50 μm and smaller than the dimension of the first aperture stop in a second horizontal direction.

For example, the semiconductor layer stack may include an AlAs layer, and forming the first aperture stop comprises an oxidation method for oxidizing the AlAs layer.

A LIDAR system includes the opto-electronic semiconductor device described above.

Further embodiments relate to an optoelectronic apparatus comprising the described optoelectronic semiconductor device.

### BRIEF DESCRIPTION OF THE DRAWINGS

The accompanying drawings serve to provide an understanding of exemplary embodiments of the invention. The drawings illustrate exemplary embodiments and, together with the description, serve for explanation thereof. Further exemplary embodiments and many of the intended advantages will become apparent directly from the following detailed description. The elements and structures shown in the drawings are not necessarily shown to scale relative to each other. Like reference numerals refer to like or corresponding elements and structures.

FIG. 1A schematically illustrates components of an optoelectronic semiconductor device according to embodiments.

FIG. 1B illustrates an aperture stop.

FIG. 1C shows a configuration of an optoelectronic semiconductor device according to embodiments.

FIGS. 2A and 2B illustrate the configuration of an opto-electronic semiconductor device according to further embodiments.

FIG. 2C illustrates characteristics of an optoelectronic semiconductor device according to embodiments.

FIG. 2D shows a configuration of an optoelectronic semiconductor device according to further embodiments.

FIGS. 3A to 3C illustrate an optoelectronic semiconductor device according to further embodiments.

FIGS. 4A to 4H show examples of aperture stops usable in optoelectronic semiconductor devices.

FIG. 5 illustrates a method of manufacturing an optoelectronic semiconductor device.

FIG. 6A shows the configuration of an optoelectronic semiconductor device according to further embodiments.

FIG. 6B shows an apparatus for manufacturing a component of the optoelectronic semiconductor device.

FIGS. 7A and 7B show a cross-sectional view of an opto-electronic semiconductor device according to further embodiments.

FIG. 8 summarizes a method according to embodiments.

FIG. 9A shows a LIDAR system according to embodiments.

FIG. 9B shows an optoelectronic apparatus according to embodiments.

### DETAILED DESCRIPTION

In the following detailed description, reference is made to the accompanying drawings, which form a part of the disclosure and in which specific exemplary embodiments are shown for purposes of illustration. In this context, directional terminology such as “top”, “bottom”, “front”, “back”, “over”, “on”, “in front”, “behind”, “leading”, “trailing”, etc. refers to the orientation of the figures just described. As the components of the exemplary embodiments may be positioned in different orientations, the directional terminology is used by way of explanation only and is in no way intended to be limiting.

The description of the exemplary embodiments is not limiting, since other exemplary embodiments may also exist and structural or logical changes may be made without departing from the scope as defined by the patent claims. In particular, elements of the exemplary embodiments described below may be combined with elements from others of the exemplary embodiments described, unless the context indicates otherwise.

The terms “wafer” or “semiconductor substrate” used in the following description may include any semiconductor-based structure that has a semiconductor surface. Wafer and structure are to be understood to include doped and undoped semiconductors, epitaxial semiconductor layers, supported by a base, if applicable, and further semiconductor structures. For example, a layer of a first semiconductor material may be grown on a growth substrate made of a second semiconductor material, for example a GaAs substrate, a GaN substrate, or an Si substrate, or of an insulating material, for example sapphire.

Depending on the intended use, the semiconductor may be based on a direct or an indirect semiconductor material. Examples of semiconductor materials particularly suitable for generating electromagnetic radiation include, without limitation, nitride semiconductor compounds, by means of which, for example, ultraviolet, blue or longer-wave light may be generated, such as GaN, InGaN, AlN, AlGaN, AlGaInN, AlGaInBN; phosphide semiconductor compounds by means of which, for example, green or longer-wave light may be generated, such as GaAsP, AlGaInP, GaP, AlGaP; and other semiconductor materials such as GaAs, AlGaAs, InGaAs, AlInGaAs, SiC, ZnSe, Zno, Ga₂O₃, diamond, hexagonal BN, and combinations of the materials mentioned. The stoichiometric ratio of the compound semiconductors may vary. Other examples of semiconductor materials may include silicon, silicon germanium, and germanium. In the context of the present description, the term “semiconductor” also includes organic semiconductor materials.

The term “substrate” generally includes insulating, conductive or semiconductor substrates.

The term “vertical”, as used in this description, is intended to describe an orientation which is essentially perpendicular to the first surface of a substrate or semiconductor body. The vertical direction may, for example, correspond to a direction of growth when layers are grown.

The terms “lateral” and “horizontal”, as used in the present description, are intended to describe an orientation or alignment which extends essentially parallel to a first surface of a substrate or semiconductor body. This may be the surface of a wafer or a chip (die), for example.

The horizontal direction may, for example, be in a plane perpendicular to a direction of growth when layers are grown.

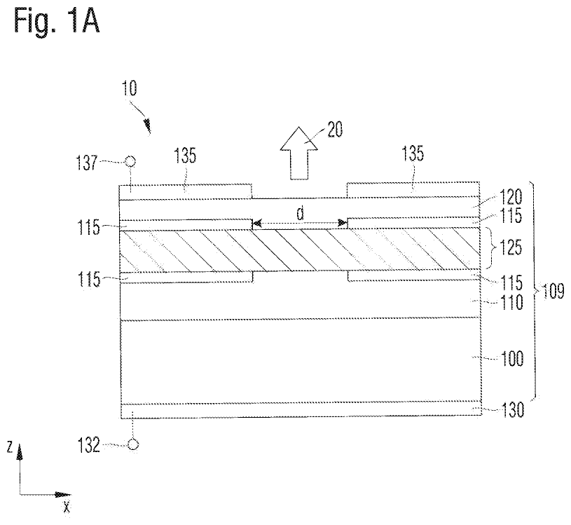

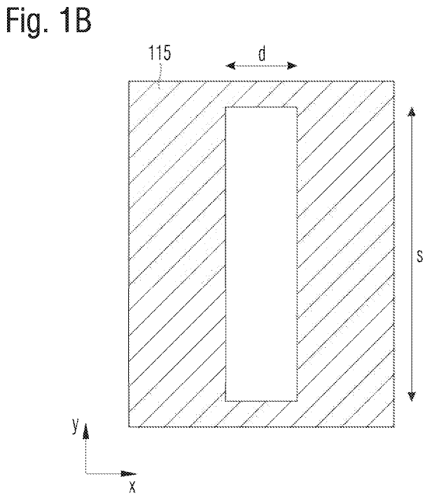

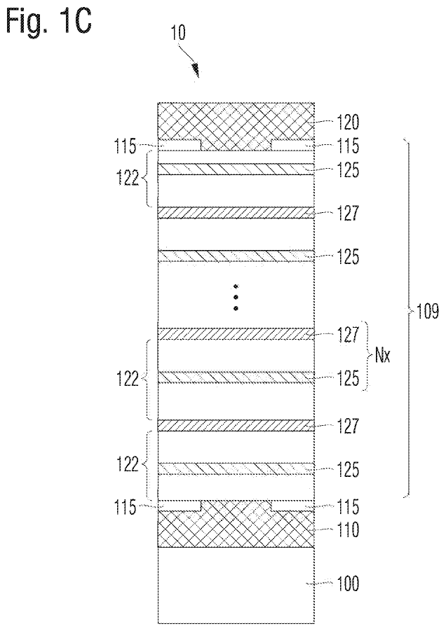

FIG. 1A schematically shows a cross-sectional view of an optoelectronic semiconductor device according to embodiments. The optoelectronic semiconductor device comprises a semiconductor layer stack 109 in which a surface-emitting laser diode is formed. The semiconductor layer stack 109 includes a first rectangular aperture stop 115. A dimension of the first aperture stop 115 in a first horizontal direction is smaller than 50 μm. The surface-emitting laser diode represents a vertical cavity surface-emitting laser (VCSEL). The latter comprises a first resonator mirror 110, a second resonator mirror 120, and an active zone 125.

The optoelectronic semiconductor device comprises an optical resonator formed between the first and second resonator mirrors 110, 120. In this case, the first and second resonator mirrors 110, 120 may each be formed as a DBR (Distributed Bragg Reflector) layer stack and may comprise a plurality of alternating thin layers of different refractive indices. The thin layers may each be composed of a semiconductor material or else from a dielectric material. For example, the layers may alternately have a high refractive index (n>3.1 when using semiconductor materials, n>1.7 when using dielectric materials) and a low refractive index (n<3.1 when using semiconductor materials, n<1.7 when using dielectric materials). For example, the layer thickness may be λ/4 or a multiple of λ/4, with λ indicating the wavelength of the light to be reflected in the corresponding medium. The first or second resonator mirrors may comprise, for example, 2 to 50 individual layers. A typical layer thickness of the individual layers may be approximately 30 to 150 nm, for example 50 nm. The layer stack may furthermore include one or two or more layers thicker than about 180 nm, for example, thicker than 200 nm.

The first resonator mirror 110 may include semiconductor layers of a first conductivity type, such as p-type. The second resonator mirror 120 may include semiconductor layers of a second conductivity type, such as n type. According to further embodiments, the first and/or the second resonator mirrors 110, 120 may be composed of dielectric layers. In this case, semiconductor layers of the first conductivity type may be disposed between the first resonator mirror 110 and the active zone 125. Furthermore, semiconductor layers of the second conductivity type may be disposed between the second resonator mirror 120 and the active zone 125.

The active zone 125 may, for example, comprise a pn junction, a double heterostructure, a single quantum well (SQW) structure or a multiple quantum well (MQW) structure for generating radiation. The term “quantum well structure” does not imply any particular meaning here with regard to the dimensionality of the quantization. Therefore it includes, among other things, quantum wells, quantum wires and quantum dots as well as any combination of these layers. For example, the materials of the active zone 125 may include GaAs. An emission wavelength of the surface-emitting laser diode may thus be in a range from 100 nm to 1500 nm. According to further embodiments, materials of the active zone may include GaN (or Ga or N) or GaAs (or As). An emission wavelength of the surface-emitting laser diode may, for example, be in a range from 420 nm to 980 nm, for example between 850 nm and 950 nm. According to further embodiments, materials of the active zone may include InP. An emission wavelength of the surface-emitting laser diode may, for example, be in a range from 1200 to 1600 nm.

An aperture stop 115 is arranged in the semiconductor layer stack 109. The aperture stop 115 is, for example, arranged adjacent to the first and/or the second resonator mirrors 110, 120. For example, the aperture stop 115 is insulating and therefore limits the current flow and thus the injection of charge carriers onto the region between the edge parts of the aperture stop 115. For example, the first aperture stop 115 is formed to be rectangular. The dimension of the first aperture stop 115 in a first horizontal direction differs from the dimension of the first aperture stop 115 in a second horizontal direction. As shown in FIG. 1A, the dimension of the first aperture stop in the first horizontal direction, for example the x-direction, is smaller than 50 μm.

FIG. 1B shows a plan view of the first aperture stop. As may be seen, the dimension d of the first aperture stop 115 in the first direction, for example the x-direction, is substantially smaller than the dimension s in the second direction, for example the y-direction. For example, d may be smaller than 50 μm, for example smaller than 20 μm, for example about 10 μm. For example, the dimension d may be greater than 5 μm. Furthermore, the dimension s of the aperture stop 115 in the second direction may be greater than 100 μm, for example greater than 200 μm. The dimension s may, for example, be about 1 mm or more. For example, the dimension s may be smaller than 2 mm. For example, the ratio of the dimensions in the first and second directions d:s may be smaller than 5:100, for example smaller than 3:100.

In this way, a surface-emitting laser diode having a near field of an edge-emitting laser is provided. For example, the near field may be formed in a linear shape. Such a design of the near field may be favorable for applications such as LIDAR systems or for other applications in which, for example, a region is to be scanned over a large angular range with an approximately constant dimension in a direction perpendicular thereto. In this case, for example, according to embodiments, the near field is not formed to be approximately circular, but rather of linear shape. The near field is thus similar to the near field of an edge-emitting laser.

Furthermore, when using the aperture stop described, a very high beam quality is achieved. Due to the small dimension d in the first direction, the number of modes forming in the first direction is reduced. In particular, if d is smaller than approximately 15 μm, only one mode may form in the first direction. As a result, a high beam quality and thus a low value for M² is achieved. As a further result, the laser beam generated can be focused very well, at least in the first direction, and may be formed with comparatively small optics, as a result of which compact systems may be realized.

Due to the fact that the laser is formed as a surface-emitting laser, the change in wavelength with temperature is significantly reduced compared to an edge-emitting laser and is less than approximately 0.1 nm/K.

According to embodiments, the surface-emitting laser diode comprises a plurality of laser elements 122 stacked one above the other. This is illustrated, for example, in FIG. 1C. A first resonator mirror 110 is disposed over a substrate 100. Moreover, an aperture stop 115 is disposed over the first resonator mirror 110. The semiconductor layer stack 109 now includes a plurality of active zones 125 which are interconnected, for example, via tunnel junctions 127. In this way, the semiconductor layer stack 109 may include more than three, for example approximately six or more than six, laser elements 122. Laser elements 122 may further comprise suitable semiconductor layers of the first and second conductivity types, each adjacent to and connected to active region 125.

The tunnel junctions 127 may in each case comprise highly p++-doped layers and n++-doped layers, through which the individual laser elements 122 may be connected to one another. According to embodiments, the layer thicknesses of the individual semiconductor layers of the laser elements 122 are each be dimensioned such that the tunnel junctions 127 are each arranged at nodes of the standing wave that is formed. In this manner, the emission wavelength may be further stabilized. By stacking several laser elements 122 one above the other, high power densities of the emitted laser beam may be achieved. For example, such a surface-emitting semiconductor laser may emit a power of 75 W at 12 A.

According to further embodiments, the optoelectronic semiconductor device may comprise further aperture stops.

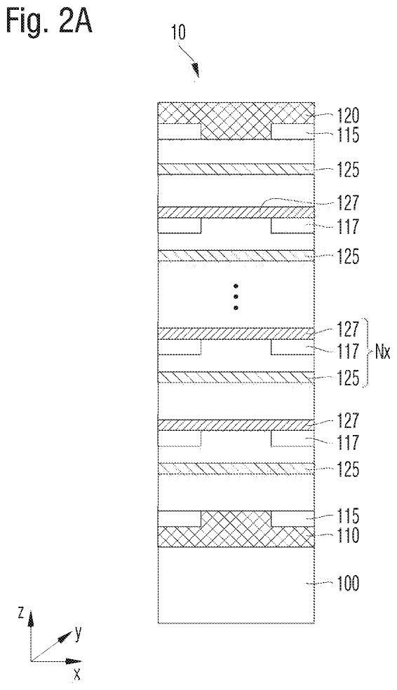

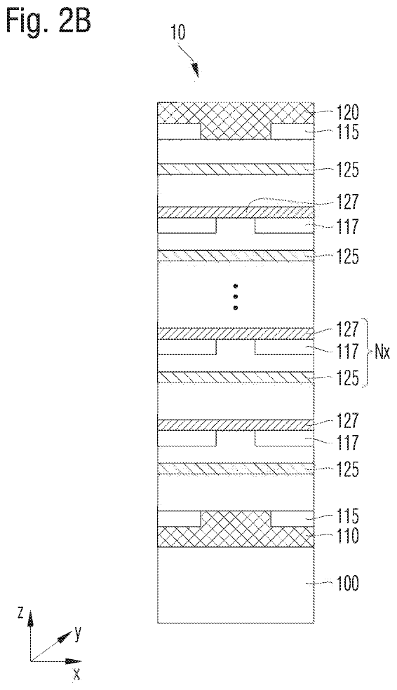

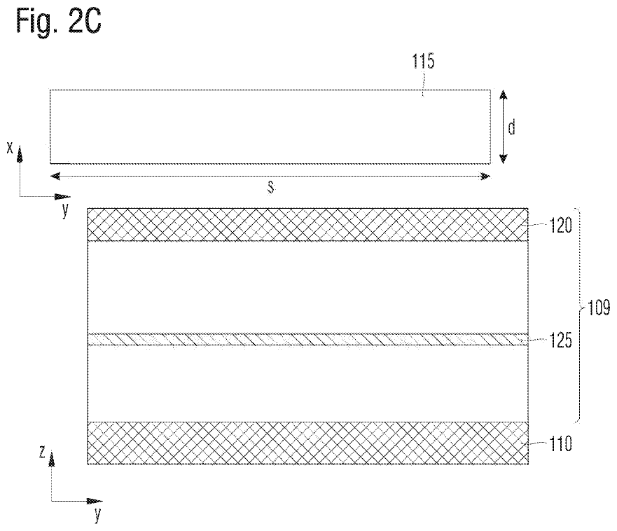

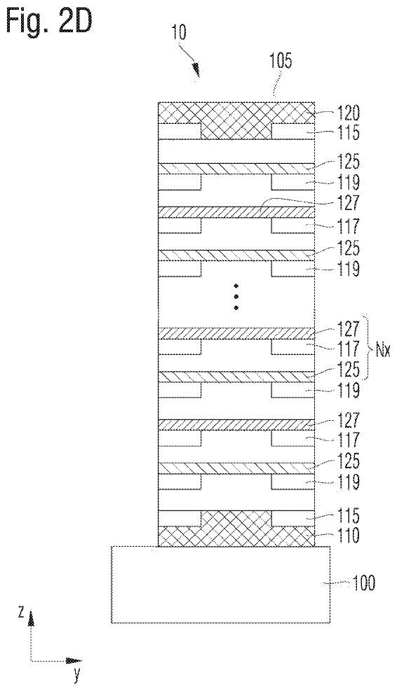

As shown in FIG. 2A, a second aperture stop 117 may, for example, be arranged adjacent to the tunnel junction 127. For example, the second aperture stop 117 may be adjacent to the tunnel junction 127. The distance between the second aperture stop 117 and the tunnel junction 127 is smaller than the distance between the second aperture stop 117 and the active zone 125, for example. A dimension of the second aperture stop 117 in the first horizontal direction is smaller than 50 μm. That is, the aperture stop may cause restriction in the first direction only. For example, the aperture stop 117 may be disposed on the tunnel junction 127 side facing a p-doped region. In this case, since the charge carrier mobility of holes is smaller than that of electrons, lateral diffusion may not take place very fast, so that the effect of the second aperture stop 117 is more marked on the p side than on the n side. The dimension of the second aperture stop 117 in the first direction may be the same as the dimension of the first aperture stop 115 in the first direction, or may also be different.

This is illustrated, for example, in FIG. 2B where the dimension of the second aperture stop 117 in the first direction is smaller than the dimension of the first aperture stop 115 in the first direction.

FIG. 2C, in the upper part, shows a plan view of the aperture stop 115. For example, dimension d in the x-direction may be smaller than 40 μm. Furthermore, dimension S in the y-direction may be in the range of 1 mm. The lower part of FIG. 2C shows a schematic cross-sectional view of the surface-emitting laser. As may be seen, such a configuration in which the active zone 125 is arranged between the first resonator mirror 110 and the second resonator mirror 120 enables laser emission to take place in the y-direction. This means that the lateral flanks of the semiconductor layer stack 109 may optionally act as resonator mirrors. For this reason, further measures may be taken in order to suppress laser emission in the horizontal or y-direction.

FIG. 2D shows a schematic cross-sectional view of the optoelectronic semiconductor device along the y-direction, i.e. the longer side of the first aperture stop 115. As shown in FIG. 1D, it may be expedient to provide a third aperture stop 119 adjacent to the active zone, wherein a dimension of the third aperture stop in the second horizontal direction is greater than 100 μm. For example, the third aperture stop 119 may directly adjoin the active zone. A distance between the active zone 125 and the third aperture stop 119 may be smaller than the distance between the active zone 125 and the tunnel junction 127. In this way, no current is impressed into the active zone 125 in this region. Rather, high absorption of electromagnetic radiation takes place in this region. Accordingly, laser activity in the horizontal direction may be suppressed.

According to further embodiments, the first aperture stop may not have any restriction along the second direction, i.e. there may be no restriction of the current along the second direction. Alternatively, during patterning of a mesa, the land may be virtually unlimited in length or else smaller than 10 mm, for example smaller than 5 mm or 2 mm. In this way, the laser is not pumped all the way along the second direction and high absorption occurs in the region of the active zone 125 where the laser is not pumped. In this way as well, laser activity in the horizontal direction may be limited.

The semiconductor layer stack 109 may be patterned into a mesa. According to embodiments, absorbent material 107 may be disposed over a sidewall 106 of the mesa 105. For example, the absorbent material 107 may be disposed over all sidewalls 106 of the mesa 105. The absorbent material 107 may also be arranged only over those side walls 106 that extend along the first direction.

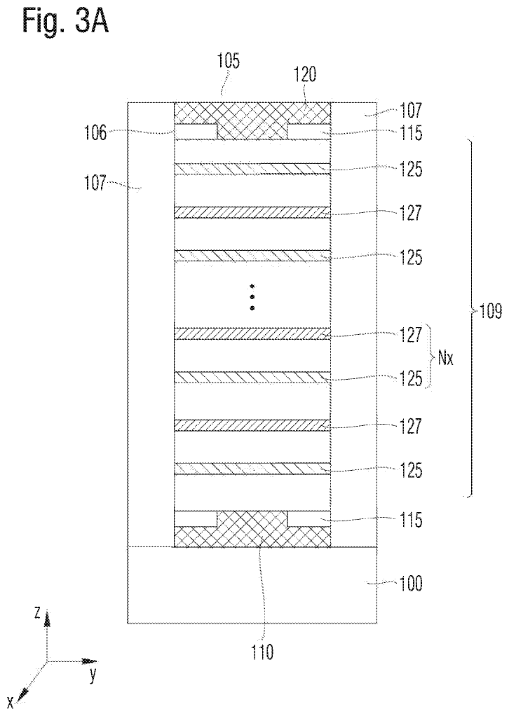

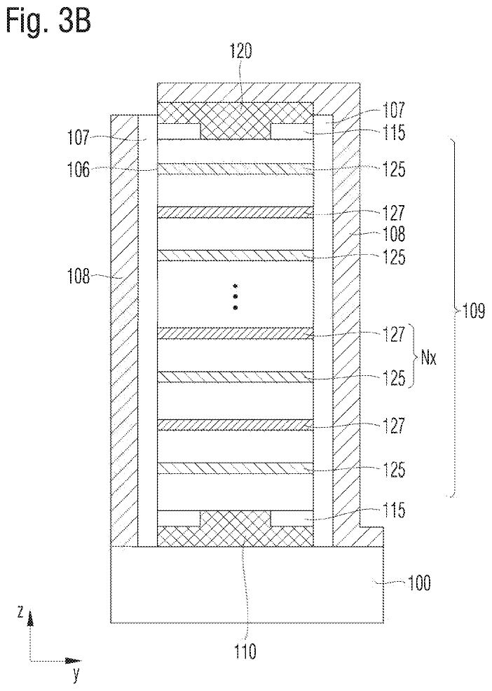

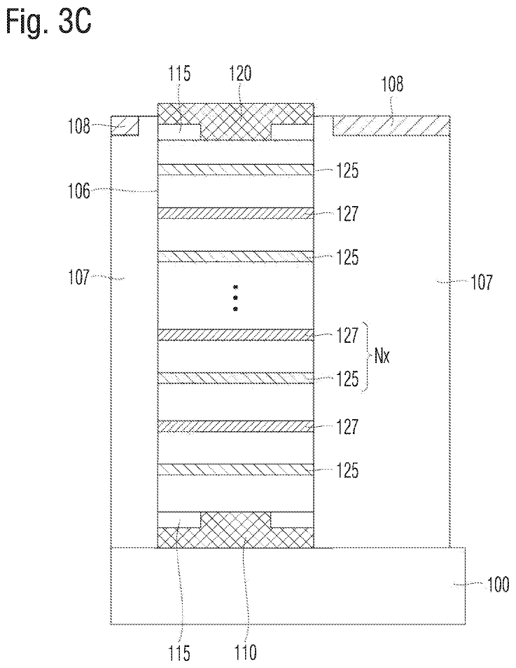

FIG. 3A shows a cross-sectional view of the optoelectronic semiconductor device along the second direction, i.e. along the y-direction. As shown in FIG. 3A, an absorbent material 107 may be disposed on a sidewall 106 of the mesa 105. For example, the absorbent material 107 may be a semiconductor material having a band gap smaller than that corresponding to a wavelength of the laser light. For example, an absorbent material 107 may comprise InAs, InP, InSb, CdSe, CdTe, HgSe, HgTe, and others. For example, a refractive index of the absorbent material may be greater than the refractive index of the material of the active zone 125.

In this manner, horizontal reflectance in the second direction on the side wall is suppressed. Overall, on the one hand, reflectance is thus reduced. On the other hand, absorption of the resultant electromagnetic radiation is effected by the absorbing material 107, resulting in suppression of laser activity in the horizontal direction. According to further embodiments, the absorbent material may also be carbon, for example having a refractive index of 2.0, TiO₂ having a refractive index of 2.5 to 3.1, SiC having a refractive index of 2.7, ZnS having a refractive index of 2.5, diamond having a refractive index of 2.4, or a mold material.

In addition, according to further embodiments, a metallization layer 108 may be provided on the sidewalls 106 of the mesa 105. For example, as in shown FIG. 3A, a metallization 108 extends along a side wall 106 of the mesa 105, for example a side wall 106 along the first direction from a region of the second resonator mirror 120 to the substrate 100. In this way, heat generated in the optoelectronic semiconductor device may be better dissipated. Additionally, the metallization 108 serves as a current supply.

FIG. 3C shows a schematic cross-sectional view of the optoelectronic semiconductor device according to further embodiments. Here, unlike in the representation in FIG. 3B, the metallization is provided as a horizontal layer, for example at the level of the second resonator mirror 120. In this case too, the metallization may dissipate the heat particularly well. The metallization 108 also serves as a current supply. By providing the metallization 108, unlike in FIG. 3B, as a horizontal layer, it may be formed with any layer thickness, as a result of which the maximum current to be impressed may be adjusted. The absorbent material 107 may insulate the metallization 108 from the substrate 100.

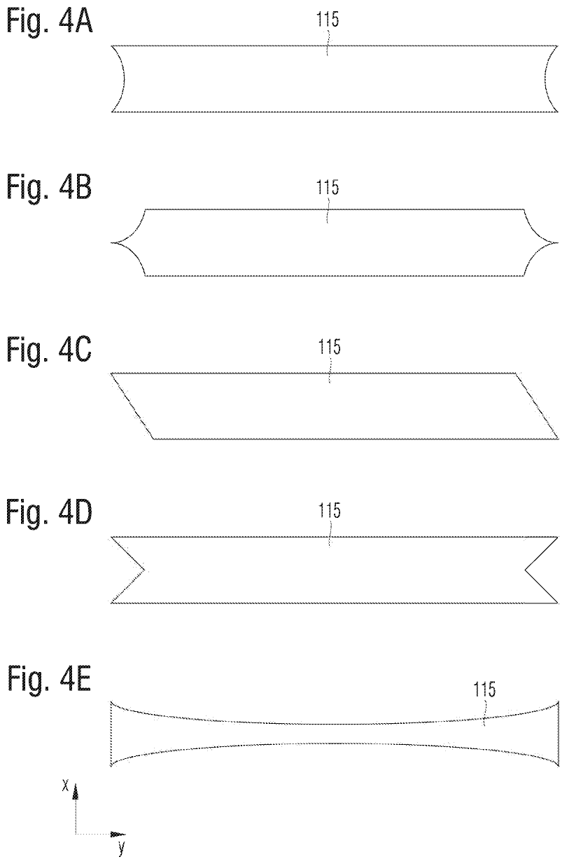

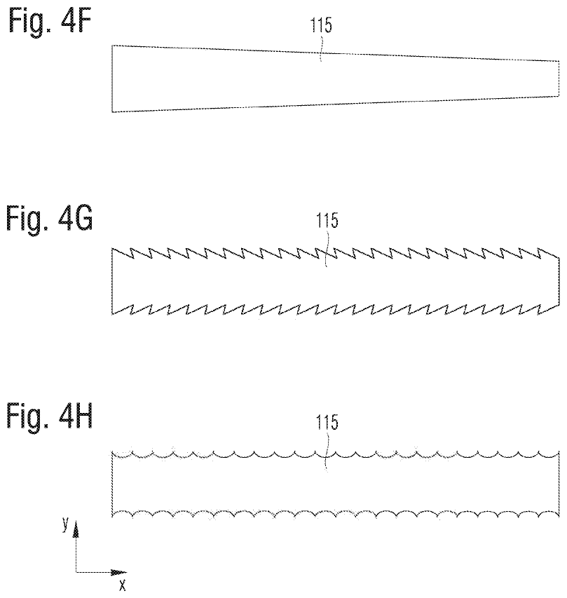

According to further embodiments, a lateral or horizontal laser operation may be further reduced by a corresponding configuration of the first aperture 115. For example, the side wall of the aperture stop 115 may comprise concave areas along the first direction. Furthermore, the side wall may be tapered along the first direction. According to further embodiments, the side wall of the aperture stop 115 may also be formed concave along the second direction. As shown in FIG. 4F, the sidewall may be tapered along the second direction. As illustrated in FIGS. 4G and 4H, the sidewall may be patterned along the second direction. For example, it may be formed to be sawtoothed, as shown in FIG. 4G. Furthermore, it may comprise a plurality of concave regions as shown in FIG. 4H.

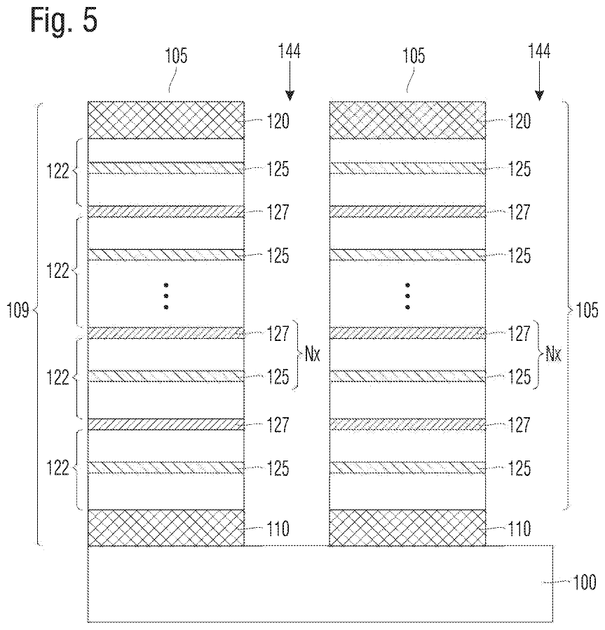

FIG. 5 illustrates a method of manufacturing the opto-electronic semiconductor device according to embodiments. A semiconductor layer stack 109 is grown on a substrate 100. The semiconductor layer stack 109 comprises layers for forming the first resonator mirror 110, the individual laser elements 122, the respective tunnel junctions 127, and the second resonator mirror 120. For example, some of the semiconductor layers may include AlAs. These may be arranged in particular at locations of the semiconductor layer stack 109 at which aperture stops are to be formed. The semiconductor layer stack 109 is then patterned into individual mesas. After photolithographic patterning, an etching process is performed so that the semiconductor layer stack 109 is divided into individual mesas 105.

Subsequently, a treatment 144 is carried out in hot steam. This treatment oxidizes a portion of the AlAs layers to Al₂O₃, which is electrically insulating. For example, the AlAs layers for forming the aperture stops at different positions of the semiconductor layer stack 109 may each have a different Al content in order to effect oxide growth at different rates. After etching the individual mesas, filling of the trenches may, for example, take place, for example using the absorbent material 107, as represented in FIGS. 3A to 3C. Patterning of the semiconductor layer stack 109 into mesas is conducted by photolithographic and etching processes. The dimensions of the mesa are suitably adjusted so that, after oxidation of the AlAs, the resulting aperture stop layer has the desired dimensions.

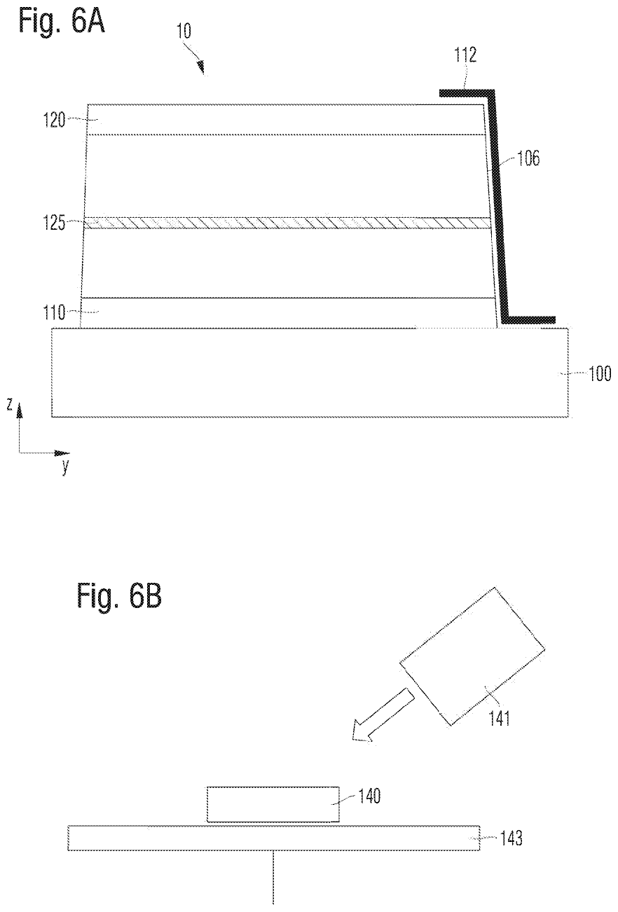

FIG. 6A shows a cross-sectional view of the optoelectronic semiconductor device in the y-z plane, i.e. along the longitudinal side of the aperture stop.

In addition to the components described above, the optoelectronic semiconductor device 10 includes an absorbent semiconductor layer 112, for example of germanium, over the sidewall 106 of the mesa. At about 850 nm, i.e. the wavelength of a GaAs laser, for example, germanium has a refractive index of 4.65. The refractive index of germanium is therefore greater than that of GaAs. In this way, there is little reflection at the interface between the active zone 125 and the adjacent semiconductor layer 112. Accordingly, the quality of the resonator which is formed is very poor in the lateral direction. Moreover, Ge has a band gap of 0.8 eV, which corresponds to about 1550 nm. That is, IR radiation emitted by the active zone 125, for example, is very well absorbed by the germanium-containing absorbing layer 107. In this way, laser activity in the horizontal direction may be very easily avoided.

According to further embodiments, the absorbent material may also be carbon, for example having a refractive index of 2.0, TiO₂ having a refractive index of 2.5 to 3.1, SiC having a refractive index of 2.7, ZnS having a refractive index of 2.5, diamond having a refractive index of 2.4, or a mold material.

For example, Ge may be sputtered or evaporated. FIG. 6B illustrates a schematic view of a apparatus for applying an absorbent semiconductor layer 122 over the sidewall 106 of the mesa 105. As shown in FIG. 6B, the sputtering source 141 may, for example, be arranged to perform oblique deposition of the material. In this way, vertical or nearly vertical side walls 106 of the mesa may be coated using the sputtering source 141, so that coverage of the side walls is obtained. The wafer 140 having the individual patterns, as shown, for example, in FIG. 6A, is disposed over a corresponding rotating holder 143.

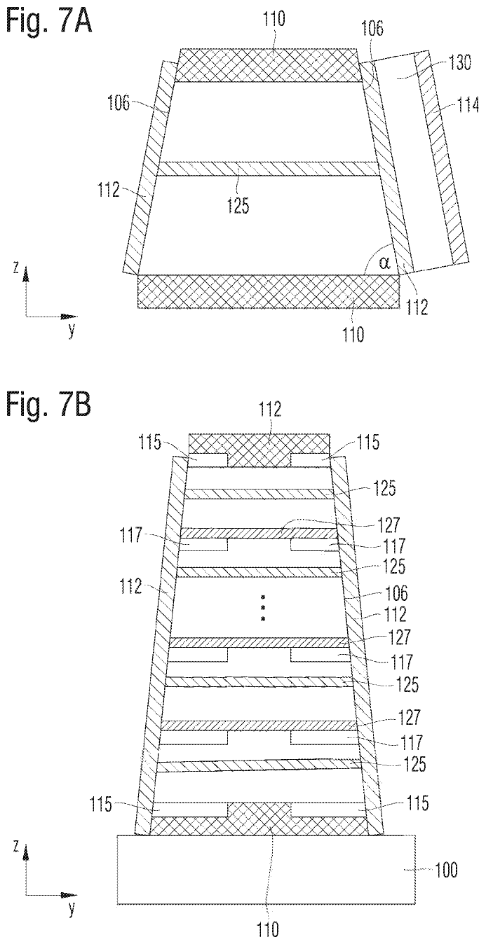

FIG. 7A shows a cross-sectional view of the optoelectronic semiconductor device according to further embodiments. The cross-sectional view shown in FIG. 7A is taken along the y-z plane, i.e. it extends along the longer direction of the aperture stop. For the sake of simplicity, the aperture stop is omitted. However, it is self-evident that any of the previously discussed aperture stops may be provided therein. As shown in FIG. 7A, an absorbent semiconductor layer 112 is disposed over the sidewall 106 of the mesa 105. Furthermore, an intermediate layer 113 may be provided over the absorbent semiconductor layer. Moreover, a conductive layer 114 may be disposed over the intermediate layer 113. For example, the intermediate layer 113 may be an insulating layer. The layer 113 may have a thickness greater than 50 nm, for example. It may be a single layer or may be composed of several layers. The insulating layer 113 may include, for example, SiN, SiO, AlO, or a combination of these materials. The intermediate layer 113 may be provided to protect the absorbent semiconductor layer 112 and to prevent oxidation of this layer, if required. The absorbent semiconductor layer 112 may, for example, have a layer thickness greater than 100 nm. For example, in the case of an appropriate layer thickness, a large portion of the incident electromagnetic radiation of smaller wavelength is absorbed. According to further embodiments, the intermediate layer 113 may also comprise an absorbent material. In addition, the conductive layer 114 may be provided for supplying current.

As further illustrated in FIG. 7A, the mesa may not be patterned with exactly vertical sidewalls 106. Alternatively, the mesa sidewalls 106 may also be sloping. In this way, the quality of a possible horizontal resonator may be further reduced.

FIG. 7B illustrates a cross-sectional view of an opto-electronic semiconductor device according to further embodiments along the y-z direction. In FIG. 7B, the first aperture stop 115 and the optional second aperture stop 117 are illustrated. In addition, a third aperture stop 119 (not shown) may also be provided in FIG. 7B. The side wall 106 of the mesa is again tapered, i.e. it does not extend in an exactly perpendicular manner to the horizontal plane, but at an angle other than 90°. An absorbent semiconductor layer 112 is again provided over the mesa sidewalls 106.

An etching of the mesa 105 may be performed using a dry etching process so that that the profile shown in FIGS. 7A and 7B results. Typically, the lower portion of the semiconductor layer stack 109 is not etched as quickly as the upper portion of the semiconductor layer stack. For this reason, a mesa structure having sloping side walls is formed. For example, a horizontal dimension of the mesa tapers from bottom to top. An angle α between a side wall and the horizontal plane may be smaller than 90°, for example, and larger than 75°, for example. This may help to facilitate application of the absorbent semiconductor layer 112 in addition.

The layers for forming the aperture stop, which may for example include AlAs, may include a respectively varying Al content. Furthermore, their layer thicknesses may each be different. In this way, the layers arranged further down in the semiconductor layer stack 109 may be oxidized more quickly. This may ensured, for example, that the aperture stops which are formed each have the same dimension, even though the diameters of the mesa differ at the different locations. In this way, the emission wavelength of the semiconductor laser may be further stabilized.

Alternatively, by adjusting the Al content, the diameter of each of the aperture stops may be adjusted.

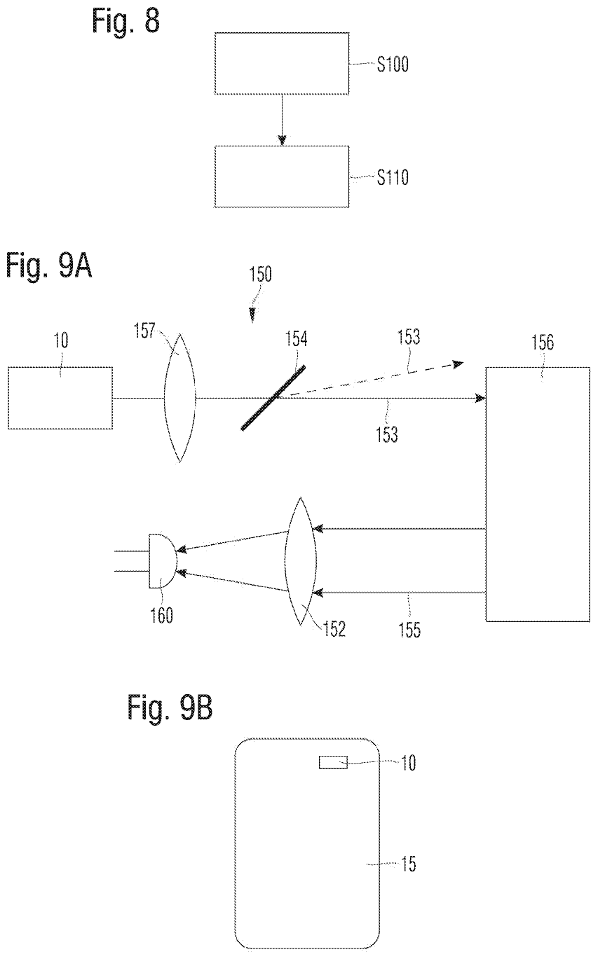

FIG. 8 summarizes a method of manufacturing an opto-electronic semiconductor device. A method of manufacturing an optoelectronic semiconductor device comprises forming (S100) a semiconductor layer stack for forming a surface-emitting laser diode, and forming (S110) a first aperture stop. A dimension of the first aperture stop in a first horizontal direction is smaller than 50 μm and smaller than the dimension of the first aperture stop in a second horizontal direction.

For example, forming the semiconductor layer stack may comprise forming an AlAs layer. Forming (S110) the first aperture stop may comprise an oxidation method for oxidizing the AlAs layer. The Al content of the AlAs layer may be adjusted in accordance with a dimension of the first aperture stop to be achieved.

FIG. 9A shows a schematic arrangement of a LIDAR system 150 in which the described optoelectronic semiconductor device 10 may be used. The typically pulsed laser radiation emitted by the optoelectronic semiconductor device 10 is transmitted, for example, by collimator optics 157 and a deflection/scanning unit 154. The object beam 153 is irradiated onto and reflected by an object 156. This results in the reflected beam 155. The reflected beam 155 is provided to a detector 160 by receiving optics 152. The distance of the object 156 may be determined from the time difference between transmitting the laser pulse and receiving the laser pulse.

By virtue of the fact that the semiconductor laser may be operated at a stable wavelength even at variable temperatures, it is possible to use a narrow-band detector. For example, the detector may use a narrow wavelength window smaller than 10 nm, or smaller than 5 nm, or even smaller than 1 nm. As a result, the influence of solar radiation may be reduced and the signal-to-noise ratio may be increased. As the optoelectronic semiconductor device 10 furthermore comprises the described first aperture stop 115, the near field is similar to the near field of an edge-emitting semiconductor laser. Accordingly, a wide angular range may be scanned in the horizontal direction using a comparatively small deflection of the deflection/scanning unit 154. A vertical position of the emitted laser beam may be maintained approximately constant over the wide angular range.

FIG. 9B shows an optoelectronic apparatus 15 according to embodiments. The optoelectronic apparatus 15 comprises the optoelectronic semiconductor device 10 as described above. For example, the optoelectronic apparatus 15 may be a laser scanner, a different suitable measuring device or a MEMS (“micro-electromechanical system”).

Although specific embodiments have been illustrated and described herein, those skilled in the art will recognize that the specific embodiments shown and described may be replaced by a multiplicity of alternative and/or equivalent configurations without departing from the scope of the invention. The application is intended to cover any adaptations or variations of the specific embodiments discussed herein. Therefore, the invention is to be limited by the claims and their equivalents only.

### LIST OF REFERENCES

10 optoelectronic semiconductor device
15 optoelectronic apparatus
20 emitted radiation
100 substrate
105 mesa
106 mesa sidewall
107 absorbent material
108 metallization
109 semiconductor layer stack
110 first resonator mirror
112 absorbent semiconductor layer
113 intermediate layer
114 conductive layer
115 first aperture stop
117 second aperture stop
119 third aperture stop
120 second resonator mirror
122 laser element
125 active zone
127 tunnel junction
130 first contact element
135 second contact element
137 second connection region
140 wafer
141 sputtering source
143 substrate holder
144 treatment with steam
150 LIDAR system
151 beamsplitter
152 reception optics
153 object beam
154 deflection/scanning unit
155 reflected beam
156 object
157 collimator optics
160 detector

1. An optoelectronic semiconductor device (10) comprising:
a semiconductor layer stack (109) in which a surface-emitting laser diode is formed, wherein the semiconductor layer stack (109) comprises a first aperture stop (115), and a dimension of the first aperture stop (115) in a first horizontal direction is smaller than 50 μm and smaller than the dimension of the first aperture stop (115) in a second horizontal direction, wherein the semiconductor layer stack (109) is patterned into a mesa (105) and a side wall (106) of the mesa (105) intersects a vertical direction.

2. The optoelectronic semiconductor element (10) according to claim 1, wherein the dimension of the first aperture stop (115) in the second horizontal direction is greater than 100 μm.

3. The optoelectronic semiconductor device (10) according to claim 1 or 2, wherein the surface-emitting laser diode comprises a plurality of laser elements (122) stacked one above the other.

4. The optoelectronic semiconductor device (10) according to claim 3, further comprising a tunnel junction (127) adapted to connect two adjacent ones of the plurality of laser elements (122) stacked one above the other.

5. The optoelectronic semiconductor device (10) according to claim 4, further comprising a second aperture stop (117) adjacent to the tunnel junction (127), wherein a dimension of the second aperture stop (117) in the first horizontal direction is smaller than 50 μm.

6. The optoelectronic semiconductor device (10) according to any of the preceding claims, further comprising a third aperture stop (119) adjacent to an active zone (125), wherein a dimension of the third aperture stop (119) in the second horizontal direction is greater than 100 μm.

7. The optoelectronic semiconductor device (10) according to any of the preceding claims, further comprising an absorbent material (107) on a sidewall (106) of the mesa (105).

8. The optoelectronic semiconductor device (10) of claim 7, wherein the absorbent material (107) comprises a semiconductor material having a band gap smaller than that corresponding to a wavelength emitted by the laser diode.

9. The optoelectronic semiconductor device (10) according to claim 7 or 8, wherein a refractive index of the absorbent material (107) is at least as large as the refractive index of a semiconductor material of an active zone (125) of the laser diode.

10. The optoelectronic semiconductor device (10) of any of the preceding claims, wherein a sidewall (106) of the mesa (105) is curved along the second horizontal direction.

11. The optoelectronic semiconductor device (10) of any of the preceding claims, wherein a sidewall of the first aperture stop (115) extends along a direction intersecting the first and second horizontal directions.

12. The optoelectronic semiconductor device (10) according to any of claims 1 to 10, wherein a sidewall of the first aperture stop (115) is patterned along the second direction.

13. The optoelectronic semiconductor device (10) according to any of claims 1 to 10, wherein a sidewall of the first aperture stop (115) is curved along the first or second direction.

14. A method of manufacturing an optoelectronic semiconductor device (10), comprising:
forming (S100) a semiconductor layer stack (109) for forming a surface-emitting laser diode,
patterning the semiconductor layer stack (109) into a mesa (105) such that a sidewall (106) of the mesa (105) intersects a vertical direction, and
forming (S110) a first aperture stop (115), wherein a dimension of the first aperture stop (115) in a first horizontal direction is smaller than 50 μm and smaller than the dimension of the first aperture stop (115) in a second horizontal direction.

15. The method of claim 14, wherein the semiconductor layer stack (109) comprises an AlAs layer and forming the first aperture stop (115) comprises an oxidation method for oxidizing the AlAs layer.

16. A LIDAR system (150) comprising the optoelectronic semiconductor device (10) of any one of claims 1 to 13.

17. An optoelectronic apparatus (15) comprising the optoelectronic semiconductor component (10) according to any one of claims 1 to 13.
